(19) United States
(12) Patent Application Publication
(10) Pub. No.: US 2022/0294167 A1
(43) Pub. Date: Sep. 15, 2022

(54) METHOD FOR MANUFACTURING DATA TRANSMISSION APPARATUS AND DATA TRANSMISSION APPARATUS

(71) Applicant: LUXSHARE PRECISION INDUSTRY CO., LTD., Bao'an District (CN)

(72) Inventors: Linbiao HU, Shenzhen (CN); Hua YI, Shenzhen (CN); Zuohua HUANG, Shenzhen (CN)

(73) Assignee: LUXSHARE PRECISION INDUSTRY CO., LTD., Bao'an District (CN)

(21) Appl. No.: 17/547,948

(22) Filed: Dec. 10, 2021

(30) Foreign Application Priority Data
Mar. 11, 2021 (CN) 202110265487.6
Mar. 11, 2021 (CN) 202120517862.7

(51) Int. Cl. H01R 31/06; H01R 43/20; H01R 43/24; H01R 13/6581

(52) U.S. Cl. CPC H01R 31/06; H01R 43/205; H01R 43/24; H01R 13/6581; H05K 1/117

(57) ABSTRACT

A method for manufacturing a data transmission apparatus includes the following. S1: a first connecting finger is formed at a first end of a printed circuit board. S2: a second connecting finger is formed at a second end of the printed circuit board. S3: a type-C female base is secured to the second end of the printed circuit board and electrically connected to the second connecting finger. S4: a conductive contact is attached to the first connecting finger. S5: an internal mold is encased around the printed circuit board the type-C female base, and the conductive contact is exposed out of the internal mold. S6: a metal housing is sleeved on one end of the internal mold facing away from the type-C female base, a socket is formed by the metal housing and the internal mold, and the conductive contact is exposed in the socket.

### CROSS-REFERENCE TO RELATED APPLICATION(S)

This application claims priority to Chinese Patent Application No. 202120517862.7 filed Mar. 11, 2021 and Chinese Patent Application No. 202110265487.6 filed Mar. 11, 2021, the disclosures of which are incorporated herein by reference in their entireties.

### TECHNICAL FIELD

The present disclosure relates to the technical field of data transmission and, in particular, to a method for manufacturing a data transmission apparatus and a data transmission apparatus.

### BACKGROUND

A universal serial bus (USB) type-C joint is a connector that can be plugged into a docking connector and electrically connected to the main circuit board to provide an electrical connection between the two electrical devices. Specifically, one end of the joint is a USB interface while the other end of the joint is a type-C interface.

In the related art, when a USB type-C joint is manufactured, an encapsulation housing is prepared first. A conductive terminal is then inserted into the encapsulation housing. One end of the conductive terminal is embedded into the upper surface of one end of the encapsulation housing while the other end of the conductive terminal extends outward from the other end of the encapsulation housing. A printed circuit board (PCB) is subsequently secured to the other end of the encapsulation housing and electrically connected to the other end of the conductive terminal. The type-C jack is finally connected to the end of the PCB facing away from the encapsulation housing.

It can be seen that the technique for manufacturing the USB type-C joint in the related art is relatively complex, and the finished USB type-C joint is relatively large in size.

### SUMMARY

An object of the present disclosure is to provide a method for manufacturing a data transmission apparatus and a data transmission apparatus. This method enables the data transmission apparatus to be simply-manufactured and to be shorter and smaller.

As conceived above, the present disclosure provides the solutions below.

A method for manufacturing a data transmission apparatus includes the steps below.

In S1, a first connecting finger is formed at a first end of a printed circuit board.

In S2, a second connecting finger is formed at a second end of the printed circuit board.

In S3, a type-C female base is secured to the second end of the printed circuit board and electrically connected to the second connecting finger.

In S4, a conductive contact is attached to the first connecting finger.

In S5, an internal mold is encased around the printed circuit board and the type-C female base, and the conductive contact is exposed out of the internal mold.

In S6, a metal housing is sleeved on one end of the internal mold facing away from the type-C female base, a socket is formed by the metal housing and the internal mold, and the conductive contact is exposed in the socket.

### BRIEF DESCRIPTION OF DRAWINGS

FIG. 1 is a flowchart of a method for manufacturing a data transmission apparatus according to embodiments of the present disclosure.

FIG. 2 is a view of a printed circuit board after the first connecting finger and the second connecting finger are formed according to embodiments of the present disclosure.

FIG. 3 is a view after a conductive contact is attached to a first connecting finger according to embodiments of the present disclosure.

FIG. 4 is a view after a type-C female base and a printed circuit board are assembled according to embodiments of the present disclosure.

FIG. 5 is view one after an internal mold is encased around a printed circuit board and a type-C female base according to embodiments of the present disclosure.

FIG. 6 is view two after an internal mold is encased around a printed circuit board and a type-C female base according to embodiments of the present disclosure.

FIG. 7 is a view after a metal housing is formed according to embodiments of the present disclosure.

FIG. 8 is a view illustrating the structure of a data transmissions apparatus according to embodiments of the present disclosure.

FIG. 9 is an exploded view illustrating the structure of a data transmission apparatus according to embodiments of the present disclosure.

FIG. 10 is a view illustrating the structure of a type-C female base according to the present disclosure.

FIG. 11 is a view of a data transmission apparatus according to embodiments of the present disclosure.

FIG. 12 is a view of another data transmission apparatus according to embodiments of the present disclosure.

### REFERENCE LIST

1 insulating housing
11 internal mold
12 external mold
2 metal housing
21 interference hole
3 printed circuit board
31 plughole
32 second connecting finger
33 first connecting finger
4 conductive contact
5 type-C female base
51 pin
52 contact terminal
53 female base body
54 grounding terminal
10 data line
20 connecting structure
30 first type-C plug
40 second type-C plug

### DETAILED DESCRIPTION

To make problems to be solved, adopted solutions and achieved effects of the present disclosure clearer, solutions of the present disclosure are further described below through embodiments in conjunction with drawings. It is to be understood that the embodiments described herein are intended to explain the present disclosure and not to limit the present disclosure. In addition, it should be noted that for ease of description, only the part, instead of all, related to the present disclosure is illustrated in the drawings.

In the description of the present disclosure, it should be noted that the orientations or position relations indicated by terms such as “center”, “above”, “below”, “left”, “right”, “vertical”, “horizontal”, “inside”, and “outside of” are based on orientations or position relations shown in the drawings. These orientations or position relations are intended only to facilitate and simplify description of the present disclosure, and not to indicate or imply that a device or element referred to must have such specific orientations or must be configured or operated in such specific orientations. Thus, these orientations or position relations are not to be construed as limiting the present disclosure. In addition, terms such as “first” and “second” are used merely for the purpose of description and are not to be construed as indicating or implying relative importance.

In the description of the present disclosure, it should be noted that unless otherwise expressly specified and limited, the term “mounting”, “connected to each other” or “connected” is to be construed in a broad sense, for example, as securely connected or detachably connected; mechanically connected or electrically connected; directly connected to each other or indirectly connected to each other via an intermediary; or internally connected between two elements.

For those of ordinary skill in the art, specific meanings of the preceding terms in the present disclosure may be construed based on specific situations.

The present embodiment provides a method for manufacturing a data transmission apparatus for manufacturing the data transmission apparatus. The manufacturing process is relatively simple.

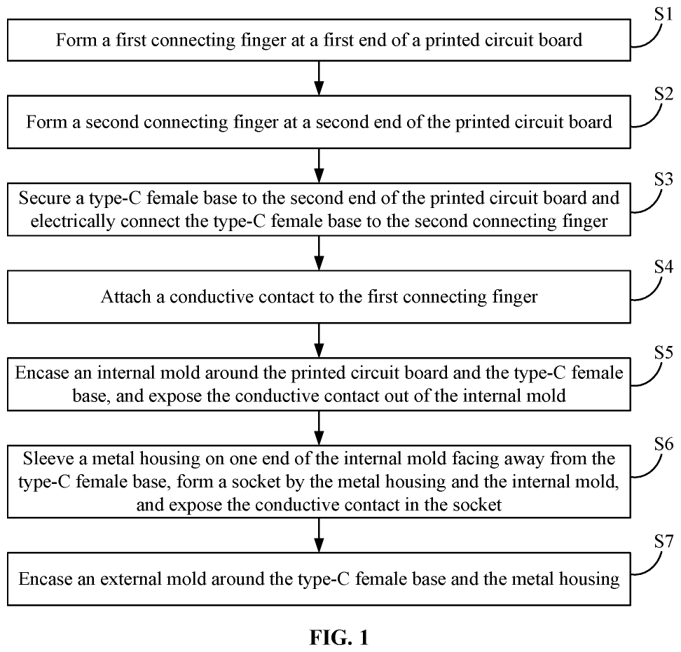

As shown in FIG. 1, the method for manufacturing a data transmission apparatus includes the steps below.

In S1, a first connecting finger 33 is formed at a first end of a printed circuit board 3.

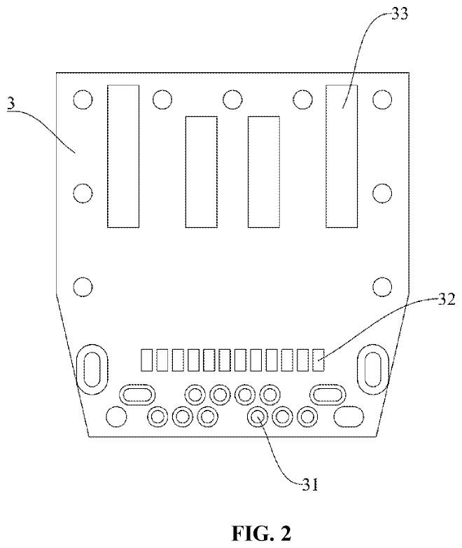

One printed circuit board 3 is prepared first, the shape of which may be determined according to the needs of the data transmission apparatus. As shown in FIG. 2, the printed circuit board 3 provided by the present embodiment is composed of a rectangular portion having a rectangular shape and a trapezoidal portion having a trapezoidal shape. The printed circuit board 3 has a first end and a second end that are opposite to each other. The first connecting finger 33 is formed at the first end of the printed circuit board 3. The number and shape of the first connecting finger 33 are disposed according to needs. It is to be noted that a plurality of conductive wires are embedded inside the printed circuit board 3. The plurality of conductive wires can be electrically connected to the first connecting finger 33 for transmitting a signal or an electrical signal. Exemplarily, four first connecting fingers 33 are provided for connection to the USB joint.

In S2, a second connecting finger 32 is formed at the second end of the printed circuit board 3.

The second connecting finger 32 is formed at the second end of the printed circuit board 3. The second connecting finger 32 may be electrically connected to the first connecting finger 33 through the conductive wires inside the printed circuit board 3. The number and shape of the second connecting finger 32 are determined according to actual needs. For example, the number of the second connecting finger 32 is the same as the number of the contact terminal 52 on the type-C female base for electrical connection to the contact terminal 52. The printed circuit board 3 after the first connecting finger 33 and the second connecting finger 32 are formed is shown in FIG. 2.

It is to be noted that the sequence of S1 and S2 may be adjusted according to actual situations. For example, the second connecting finger 32 is formed before the first connecting finger 33 is formed. Alternatively, the first connecting finger 33 and the second connecting finger 32 are formed at the same time. This is not limited in the present embodiment.

In S3, a type-C female base 5 is secured to the second end of the printed circuit board 3 and electrically connected to the second connecting finger 32.

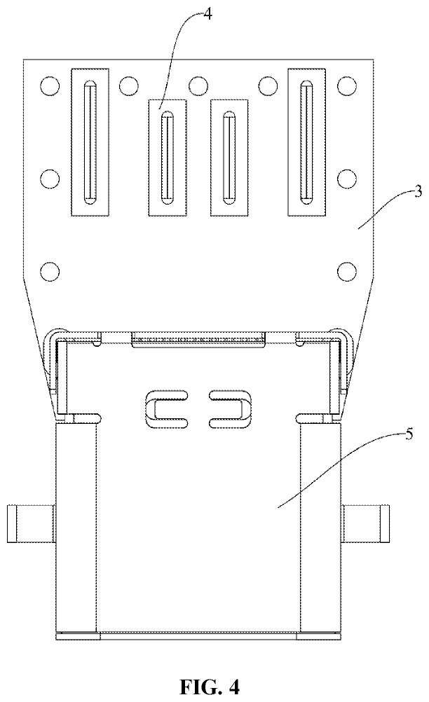

After the second connecting finger 32 is formed, the type-C female base 5 is secured to the second end of the printed circuit board 3 such that the contact terminal 52 of the type-C female base 5 is electrically connected to the second connecting finger 32 so as to electrically connect the type-C female base 5 to the first connecting finger 33 through the second connecting finger 32 and the conductive wires inside the printed circuit board 3 for transmitting data or power. FIG. 4 is a view after the type-C female base 5 and the printed circuit board 3 are assembled.

In S4, a conductive contact 4 is attached to the first connecting finger 33.

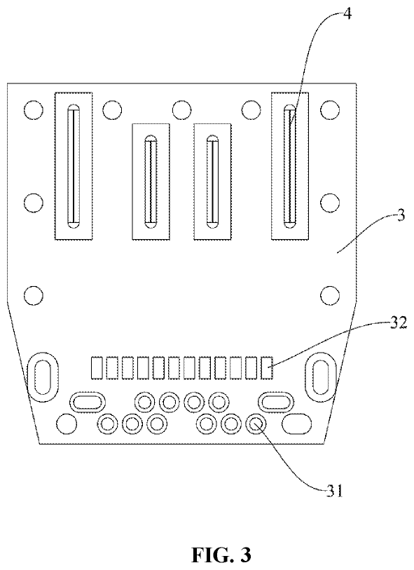

After the first connecting finger 33 is formed, the conductive contact 4 may be attached to the first connecting finger 33 for electrical connection to other structures through the conductive contact 4. A plurality of conductive contacts 4 and a plurality of first connecting fingers 33 are provided. The plurality of conductive contacts 4 are in one-to-one correspondence with the plurality of first connecting fingers 33. Each of the plurality of conductive contact 4 of is attached to a corresponding one of the plurality of first connecting fingers 33. FIG. 3 is a view after the conductive contact 4 is attached to the first connecting finger 33.

It is to be noted that the conductive contact 4 may be instantly formed on the first connecting finger 33 after the first connecting finger 33 is formed to reduce the time of the first connecting finger 33 exposed outside.

In S5, an internal mold 11 is encased around the printed circuit board 3 and the type-C female base 5, and the conductive contact 4 is exposed out of the internal mold 11.

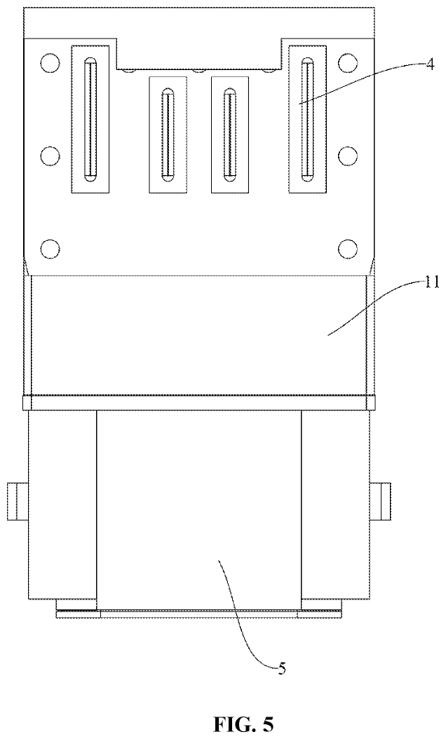

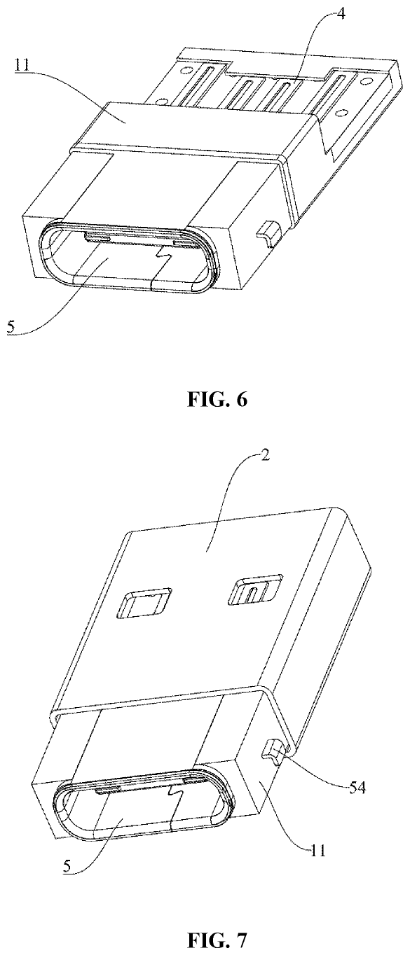

After the type-C female base 5 is secured to the printed circuit board 3, the insulating internal mold 11 is needed to encase around the printed circuit board 3 and the type-C female base 2 to improve the stability of the connection between the type-C female base 5 and the printed circuit board 3. Exemplarily, the internal mold 11 is injection molded around part of the printed circuit board 3 and part of the type-C female base 5. As shown in FIGS. 5 and 6, the internal mold 11 encases part of the printed circuit board 3 and part of the type-C female base 5. The printed circuit board 3 is encased in part to expose the conductive contact 4 so as to electrically connect the conductive contact 4 to other structures smoothly. The type-C female base 5 is encased in part so as to not increase the thickness of the data transmission apparatus.

In S6, a metal housing 2 is sleeved on one end of the internal mold 11 facing away from the type-C female base 5, a socket is formed by the metal housing 2 and the internal mold 11, and the conductive contact 4 is exposed in the socket.

After the internal mold 11 is formed, as shown in FIG. 7, the metal housing 2 is sleeved on one end of the internal mold 11 facing away from the type-C female base 5, the socket is formed by the metal housing 2 and the internal mold 11, and the conductive contact 4 is exposed in the socket, so that other structures can be inserted into the socket and electrically connected to the conductive contact 4.

Optionally, in S6, the metal housing 2 is tin soldered to the internal mold 11 so as to improve the robustness of the connection between the metal housing 2 and the internal mold 11.

In the method for manufacturing a data transmission apparatus provided by the present embodiment, with the configuration in which the first connecting finger 33 and the second connecting finger 32 are formed at both ends of the printed circuit board 3, the type-C female base 5 can be electrically connected to the printed circuit board directly through the second connecting finger 32. Compared with the manner of electrical connection by use of a conductive terminal, a smaller space is occupied so that the data transmission apparatus is shorter and smaller and so that the development of the data transmission apparatus is facilitated. Compared with the method in which a contact is disposed on an encapsulation housing in the related art, the configuration in which the conductive contact 4 is directly disposed on the first connecting finger can reduce the space occupied by the encapsulation housing, making the data transmission apparatus further smaller in size and facilitating manufacturing of the data transmission apparatus.

Further, after S6, the method for manufacturing a data transmission apparatus further includes a step below.

In S7, an external mold 12 is encased around the type-C female base 5 and the metal housing 2.

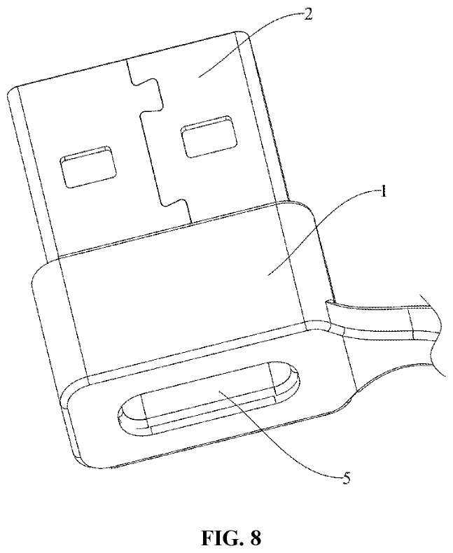

The external mold 12 may encase the rest parts except the interface of the type-C female base 5 to fully protect the type-C female base 5 so as to prevent electric leakage and other situations. As shown in FIG. 8, the external mold 12 encases part of the metal housing 2 so that when the metal housing 2 is inserted into other structures, the insertion degree can be limited through the external mold 12.

In the present embodiment, before the preceding S3, the method for manufacturing a data transmission apparatus further includes steps as follows. The second end of the printed circuit board 3 is provided with a plughole 31, and in S3, a pin 51 on the type-C female base 5 is inserted into the plughole 31 so as to connect the type-C female base 5 to the second end of the printed circuit board 3. Exemplarily, the inner wall of the plughole 31 may have a conductive structure. At the time, the type-C female base 5 may be electrically connected to the printed circuit board 3 through the pin 51 and the plughole 31, thereby improving the reliability of the connection between the type-C female base 5 and the printed circuit board 3.

The method for manufacturing a data transmission apparatus provided by the present embodiment is easy to implement and has fewer manufacturing steps and a lower cost.

The present embodiment further provides a data transmission apparatus that is manufactured by the preceding method for manufacturing a data transmission apparatus.

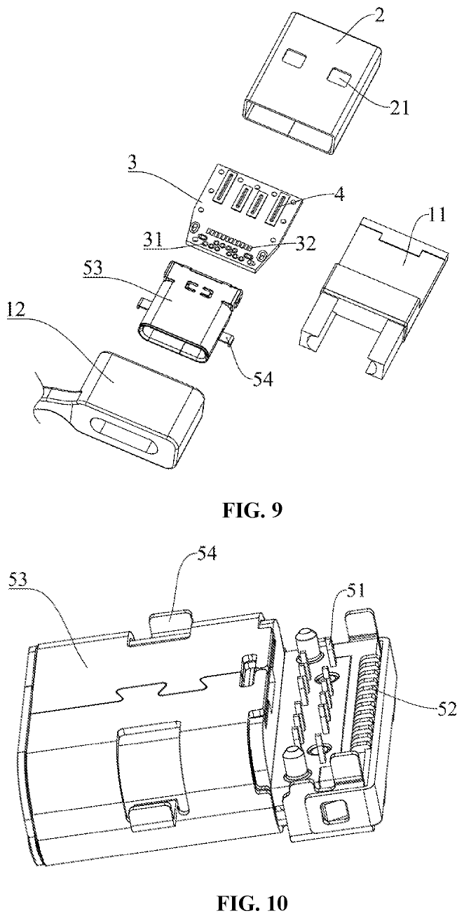

As shown in FIGS. 9 and 10, the data transmission apparatus includes an internal mold 11, a metal housing 2, a printed circuit board 3, a conductive contact and a type-C female base 5.

The metal housing 2 is connected to one end of the internal mold 11. A socket is formed by the metal housing 2 and the internal mold 11. The printed circuit board 3 is disposed inside the internal mold 11. A conductive contact 4 is attached to a first connecting finger 33 at a first end of the printed circuit board 3, and the conductive contact 4 is exposed in the socket. The type-C female base 5 is electrically secured to a second end of the printed circuit board 3 and electrically connected to a second connecting finger 32 at the second end of the printed circuit board 3. The type-C female base 5 is electrically connected to the conductive contact 4 through the printed circuit board 3.

In the data transmission apparatus provided by the present embodiment, the socket for connection to the USB interface is formed by the insulating housing 1 and the metal housing 2, and the conductive contact 4 located in the socket is directly disposed at the first end of the printed circuit board 3. Compared with the method in which a contact is disposed on an encapsulation housing in the related art, the preceding configuration can reduce the space occupied by the insulating housing 1. Compared with the manner of electrical connection by use of a conductive terminal, the type-C female base 5 is directly secured to the second end of the printed circuit board 3. In this manner, a smaller space is occupied so that the data transmission apparatus shorter and smaller and so that the development of the data transmission apparatus is facilitated.

Referring to FIGS. 9 and 10, the second end of the printed circuit board 3 has a plurality of plugholes 31, and the type-C female base 5 includes a plurality of pins 51, the plurality of pins 51 are in one-to-one correspondence with the plurality of plugholes 31, and each of the plurality of pins 51 is inserted into a corresponding one of the plurality of plugholes 31.

Further, the plurality of plugholes 31 have a positioning plughole for positioning and a signal plughole for transmitting a signal, and the plurality of pins 51 have a positioning pin and a signal pin. The positioning pin is inserted into the positioning plughole to securely connect the type-C female base 5 to the printed circuit board 3. The signal pin is inserted into and electrically connected to the signal plughole to transmit a signal or power.

Optionally, as shown in FIG. 9, a plurality of second connecting fingers 32 are disposed on the printed circuit board 3. As shown in FIG. 10, the type-C female base 5 further includes a plurality of contact terminals 52. The plurality of contact terminals 52 are in one-to-one correspondence with the plurality of second connecting fingers 32, and each of the plurality of contact terminals 52 abuts against a corresponding one of the plurality of second connecting fingers 32 so as to electrically connect the type-C female base 5 to the printed circuit board 3.

Exemplarily, one end of the type-C female base 5 facing the printed circuit board 3 has a stepped structure, that is, the thickness of the end of the type-C female base 5 is less than the thickness of the middle of the type-C female base 5. The pin 51 and the contact terminal 52 are disposed on the other surface of the stepped structure, and the second end of the printed circuit board 3 is lap joined on the stepped structure.

In the present embodiment, as shown in FIG. 10, the type-C female base 5 includes a female base body 53 and a grounding terminal 54 connected to both sides of the female base body 53. The stepped structure is electrically secured to the female base body 53. The female base body 53 is electrically secured to the second end of the printed circuit board 3 through the stepped structure. The grounding terminal 54 is in contact with the insulating housing 1 for grounding of the type-C female base 5.

Further, one side surface of the stepped surface is flush with one side of the female base body 53, and one side of the printed circuit board 3 not in contact with the stepped structure can be flush with the other side of the female base body 52 or located under the other side of the female base body 52, so that the direct connection between the printed circuit board 4 and the type-C female base 5 does not increase the thickness of the data transmission apparatus, making the data transmission apparatus smaller.

The second length of the data transmission apparatus provided by the present embodiment is about 20.2 mm, about 10 mm smaller than the second length of the data transmission apparatus in the related art, which is conducive for making the data transmission apparatus smaller.

Exemplarily, as shown in FIG. 9, an interference hole 21 for interference in other structures is disposed on the metal housing 2.

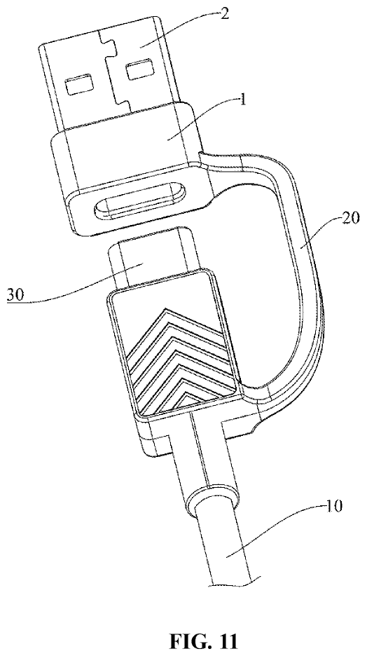

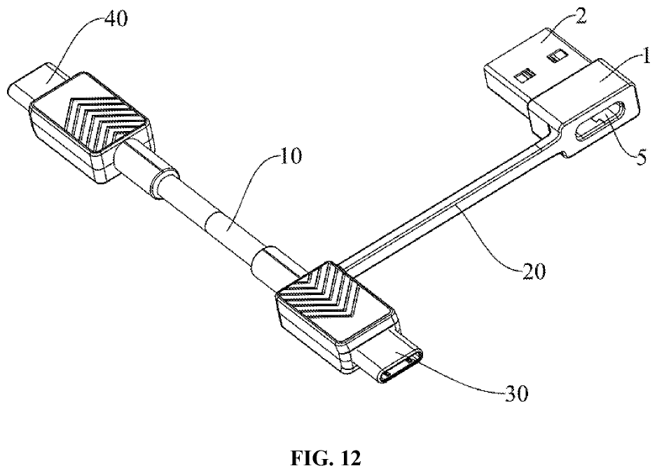

Optionally, as shown in FIGS. 11 and 12, the data transmission apparatus further includes a data line 10 that is electrically connected to the type-C female base 5.

Further, as shown in FIG. 11, the data transmission apparatus further includes a connecting structure 20 and a first type-C plug 30. One end of the connecting structure 20 is connected to the insulating housing 1 while the other end of the connecting structure 20 is connected to the housing portion of the first type-C plug 30. The first type-C plug 30 is pluggably inserted into the type-C female base 5 to enable data transmission with the type-C female base 5. One end of the data line 10 is electrically connected to the first type-C female base 30.

Further, as shown in FIG. 12, the data transmission apparatus further includes a second type-C plug 40 that is electrically connected to the other end of the data line 20 to apply to different application scenarios.

The data transmission apparatus provided by the present embodiment is relatively small in size, easy to carry and available for scenarios with high space requirements. The preceding embodiments describe only the basic principles and characteristics of the present disclosure and do not limit the present disclosure. Modifications and changes may be made in the present disclosure without departing from the spirit and scope of the present disclosure. These modifications and changes fall within the scope of the present disclosure. The scope of the present disclosure is defined by the appended claims and equivalents thereof

What is claimed is:

1. A method for manufacturing a data transmission apparatus, comprising:
S1: forming a first connecting finger at a first end of a printed circuit board;
S2: forming a second connecting finger at a second end of the printed circuit board;
S3: securing a type-C female base to the second end of the printed circuit board and electrically connecting the type-C female base to the second connecting finger;
S4: attaching a conductive contact to the first connecting finger;
S5: encasing an internal mold around the printed circuit board and the type-C female base, and exposing the conductive contact out of the internal mold; and
S6: sleeving a metal housing on one end of the internal mold facing away from the type-C female base, forming a socket by the metal housing and the internal mold, and exposing the conductive contact in the socket.

2. The method for manufacturing a data transmission apparatus according to claim 1, after S6, further comprising:
S7: encasing an external mold around the type-C female base and the metal housing.

3. The method for manufacturing a data transmission apparatus according to claim 1, before S3, further comprising providing a plughole at the second end of the printed circuit board, wherein in S3, a pin on the type-C female base is inserted into the plughole so as to connect the type-C female base to the second end of the printed circuit board.

4. The method for manufacturing a data transmission apparatus according to claim 1, wherein in S5, the internal mold is injection molded around part of the printed circuit board and part of the type-C female base.

5. The method for manufacturing a data transmission apparatus according to claim 1, wherein in S6, the metal housing is tin soldered to the internal mold.

6. The method for manufacturing a data transmission apparatus according to claim 1, wherein one end of the type-C female base has a stepped structure, and in S3, the second end of the printed circuit board is lap joined to the stepped structure.

7. A data transmission apparatus manufactured, comprising:
an internal mold;
a metal housing connected to one end of the internal mold, wherein a socket is formed by the metal housing and the internal mold;
a printed circuit board disposed inside the internal mold, wherein a conductive contact is attached to a first connecting finger at a first end of the printed circuit board, and the conductive contact is exposed in the socket; and
a type-C female base electrically secured to a second end of the printed circuit board and electrically connected to a second connecting finger at the second end of the printed circuit board, wherein the type-C female base is electrically connected to the conductive contact through the printed circuit board.

8. The data transmission apparatus according to claim 7, wherein one end of the type-C female base facing the printed circuit board has a stepped structure, and the second end of the printed circuit board is lap joined to the stepped structure.

9. The data transmission apparatus according to claim 7, wherein a plurality of plugholes are disposed on the second end of the printed circuit board, a plurality of pins are disposed on the type-C female base, the plurality of pins are in one-to-one correspondence with the plurality of plugholes, and each of the plurality of pins is inserted into and electrically connected to a corresponding one of the plurality of plugholes.

10. The data transmission apparatus according to claim 9, wherein a plurality of second connecting fingers are provided, a plurality of contact terminals are disposed on one end of the type-C female base, the plurality of contact terminals are in one-to-one correspondence with the plurality of second connecting fingers, and each of the plurality of contact terminals abuts against a corresponding one of the plurality of second connecting fingers.
